(19) United States
(12) Patent Application Publication
(10) Pub. No.: US 2022/0395792 A1
(43) Pub. Date: Dec. 15, 2022

(54) LIQUID SUPPLY SYSTEM AND LIQUID SUPPLY METHOD

(71) Applicant: CHANGXIN MEMORY TECHNOLOGIES, INC., Hefei City, Anhui (CN)

(72) Inventor: Guobiao JIANG, Hefei City, Anhui (CN)

(21) Appl. No.: 17/595,528

(22) PCT Filed: May 24, 2021
(86) PCT No.: PCT/CN2021/095611

§ 371 Date: Nov. 18, 2021

(30) Foreign Application Priority Data
Jul. 10, 2020 (CN) 202010663276.3

(51) Int. Cl. B01F 35/83

(52) U.S. Cl. CPC B01F 35/831; B01F 35/833; B01F 2101/58

(57) ABSTRACT

Embodiments of the present application provide a liquid supply system and a liquid supply method. The liquid supply system includes: a mixing tank, the mixing tank being connected to at least a first injection pipe, a second injection pipe and a replenishing pipe; the first injection pipe and the second injection pipe being configured to inject a first liquid and a second liquid into the mixing tank respectively, so as to form a mixed liquid; a parameter acquisition module configured to acquire a concentration of the first liquid in the mixed liquid; and a treatment module configured to control, based on the acquired concentration of the first liquid and a preset concentration of the first liquid, the replenishing pipe to inject the first liquid with a first flow rate into the mixing tank, or inject the second liquid with a second flow rate into the mixing tank.

### CROSS-REFERENCE TO RELATED APPLICATIONS

The present application cites Chinese Patent Application No. 202010663276.3, filed on Jul. 10, 2020 and entitled “LIQUID SUPPLY SYSTEM AND LIQUID SUPPLY METHOD,” which is incorporated herein by reference in its entirety.

### TECHNICAL FIELD

The present application relates to the field of semiconductors, and in particular to a liquid supply system and a liquid supply method.

### BACKGROUND

At present, an etching material used in a monolithic wet cleaning etching machine is mainly diluted hydrofluoric acid (DHF), and DHF may be used for a long time in a fabrication process of the monolithic wet cleaning etching machine, so a fluctuation in a concentration of DHF may seriously affect an etching amount of a wafer, thereby directly affecting a product yield.

With the progress of a semiconductor process, a line width is increasingly small, and the concentration of DHF required by the monolithic wet cleaning etching machine is required to be increasingly stable. DHF required by the monolithic wet cleaning etching machine is from a mixture of 49% hydrofluoric acid (49% HF) and deionized water (DIW).

However, it is found by the applicant that, in a related art, due to a pressure fluctuation of a main system at a facility end, it is difficult to stabilize supply mounts of 49% HF and DIW, which leads to a great fluctuation in the concentration of DHF formed by mixing, thereby affecting the product yield.

### SUMMARY

The embodiments of the present application provide a liquid supply system, including: a mixing tank, the mixing tank being connected to at least a first injection pipe, a second injection pipe and a replenishing pipe; the first injection pipe and the second injection pipe being configured to inject a first liquid and a second liquid into the mixing tank respectively, so as to form a mixed liquid; a parameter acquisition module configured to acquire a concentration of the first liquid in the mixed liquid; and a treatment module configured to control, based on the acquired concentration of the first liquid and a preset concentration of the first liquid, the replenishing pipe to inject the first liquid with a first flow rate into the mixing tank, or inject the second liquid with a second flow rate into the mixing tank, so that the concentration of the first liquid in the mixed liquid is close to the preset concentration of the first liquid.

The embodiments of the present application further provide a liquid supply method, including: acquiring a concentration of a first liquid in a mixed liquid and a preset concentration of the first liquid; and controlling, based on the acquired concentration of the first liquid and the preset concentration of the first liquid, a replenishing pipe to inject the first liquid with a first flow rate or a second liquid into a mixing tank, so that the concentration of the first liquid in the mixed liquid is close to the preset concentration of the first liquid.

### BRIEF DESCRIPTION OF DRAWINGS

FIG. 1 to FIG. 6 are schematic structural diagrams of a liquid supply system according to an embodiment of the present application;

FIG. 7 is a schematic structural diagram of a liquid supply system according to another embodiment of the present application;

FIG. 8 is a schematic structural diagram of a liquid supply system according to yet another embodiment of the present application; and

FIG. 9 is a schematic structural diagram of a liquid supply system according to still another embodiment of the present application.

### DETAILED DESCRIPTION

Currently, it is difficult to stabilize supply amounts of 49% HF and DIW in a process of replenishing an etching material of a monolithic wet cleaning etching machine, which leads to a great fluctuation in a concentration of DHF formed by mixing, thereby affecting a product yield.

In the present application, supply amounts of a first liquid and a second liquid are stabilized through an additional replenishing pipe, so that a concentration of the first liquid in a resulting mixed solution is more stable.

In order to solve the above problem, an embodiment of the present application provides a liquid supply system, including: a mixing tank, the mixing tank being connected to at least a first injection pipe, a second injection pipe and a replenishing pipe; the first injection pipe and the second injection pipe being configured to inject a first liquid and a second liquid into the mixing tank respectively, so as to form a mixed liquid; a parameter acquisition module configured to acquire a concentration of the first liquid in the mixed liquid; and a treatment module configured to control, based on the acquired concentration of the first liquid and a preset concentration of the first liquid, the replenishing pipe to inject the first liquid with a first flow rate into the mixing tank, or inject the second liquid with a second flow rate into the mixing tank, so that the concentration of the first liquid in the mixed liquid is close to the preset concentration of the first liquid.

To make the objectives, technical solutions and advantages of the embodiments of the present application clearer, the embodiments of the present application are elaborated in detail below with reference to the accompanying drawings. However, those of ordinary skill in the art may understand that, in the embodiments of the present application, numerous technical details are set forth in order to provide a reader with a better understanding of the present application. However, the technical solutions claimed in the present application can be implemented without these technical details and various changes and modifications based on the embodiments below. The embodiments below are divided for the convenience of description, and should not constitute any limitation on specific implementations of the present application. The embodiments may be combined with each other and mutually referred to without contradiction.

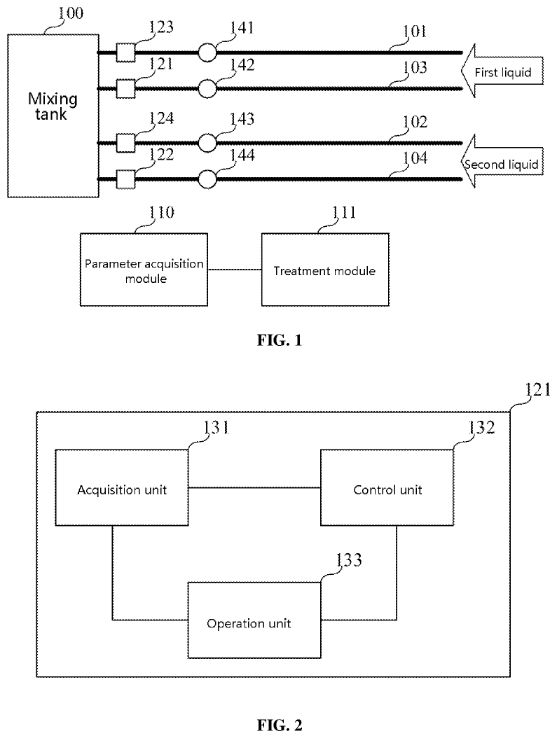

FIG. 1 to FIG. 5 are schematic structural diagrams of a liquid supply system according to an embodiment of the present application. The liquid supply system according to this embodiment is specifically described below.

Referring to FIG. 1, the liquid supply system includes: a mixing tank 100. The mixing tank 100 is connected to at least a first injection pipe 101, a second injection pipe 102 and a replenishing pipe. The first injection pipe 101 and the second injection pipe 102 are configured to inject a first liquid and a second liquid to the mixing tank 100 respectively, so as to form a mixed solution. Specifically, the first injection pipe 101 is configured to inject the first liquid into the mixing tank 100; and the second injection pipe 102 is configured to inject the second liquid into the mixing tank 100.

In this embodiment, the replenishing pipe may include a third injection pipe 103 and a fourth injection pipe 104. The third injection pipe 103 is configured to replenish the first liquid into the mixing tank 100. The fourth injection pipe 104 is configured to finely replenish the second liquid into the mixing tank 100.

In other embodiments, the replenishing pipe may also be provided with one or more injection pipes. In addition, when the replenishing pipe is provided with one injection pipe, when the first liquid in the replenishing pipe is changed to the second liquid (or when the second liquid in the replenishing pipe is changed to the first liquid), the replenishing pipe is cleaned using a cleaning liquid first to prevent a difference in concentration caused by a residual liquid in the replenishing pipe.

It should be noted that, in this embodiment, the first liquid is deionized water (DIW), the second liquid is hydrofluoric acid (49% HF), and the mixed solution formed in the mixing tank 100 is diluted hydrofluoric acid (DHF). In other embodiments, the first liquid and the second liquid may be any liquid; that is, the mixed solution in the mixing tank is any mixed solution of the first liquid and the second liquid.

In other embodiments, a mixing valve is further connected between the mixing tank and the injection pipes (including the first injection pipe, the second injection pipe and the replenishing pipe) and configured to uniformly mix the liquids injected by the first injection pipe, the third injection pipe, the second injection pipe and the fourth injection pipe and inject the liquids into the mixing tank.

A parameter acquisition module 110 is configured to acquire a concentration of the first liquid in the mixed liquid.

Specifically, the parameter acquisition module 110 includes at least one of a flowmeter and a concentration meter. The flowmeter is arranged on the injection pipes. In one example, the flowmeter is arranged in the first injection pipe 101 and the second injection pipe 102, and calculates a concentration of the first liquid in the mixed liquid of the mixing tank 100 according to flow rates of the first liquid and the second liquid injected by the first injection pipe 101 and the second injection pipe 102 into the mixing tank 100 respectively. The concentration meter is arranged in the mixing tank 100 and directly measures the concentration of the first liquid in the mixing solution, which avoids data calculation, obtains data more conveniently and faster, and saves costs.

In one embodiment, total amounts and flow fluctuation information of the liquids injected into the injection pipes can be obtained through the flowmeter, so as to replenish and adjust the mixed liquid in the mixing tank 100 in time, thereby ensuring the stability of the concentration of the first liquid or the second liquid in the mixing tank 100. In one example, the flowmeter may conduct statistics on total amounts of the first liquid and the second liquid injected by the first injection pipe 101 and the second injection pipe 102 into the mixing tank 100 respectively in a preset time, and then calculate the concentration of the first liquid in the mixed liquid of the mixing tank 100. The preset time may be 30 s, 25 s, 20 s, 15 s, 10 s or 5 s.

A treatment module 111 is configured to control, based on the acquired concentration of the first liquid and a preset concentration of the first liquid, the replenishing pipe to inject the first liquid with a first flow rate into the mixing tank 100, or inject the second liquid with a second flow rate into the mixing tank 100, so that the concentration of the first liquid in the mixed liquid is close to the preset concentration of the first liquid. Specifically, the third injection pipe 103 may be controlled to inject the first liquid with the first flow rate into the mixing tank 100, or the fourth injection pipe 104 may be controlled to inject the second liquid with the second flow rate into the mixing tank 100. In one example, the concentration of the first liquid in the mixed liquid is allowed to be within ±5% of the preset concentration of the first liquid, for example, within ±4%, ±3%, ±2% or ±1%, or further within ±0.5%.

Specifically, if the concentration of the first liquid is greater than the preset concentration of the first liquid, the fourth injection pipe 104 is controlled to inject the second liquid with the second flow rate into the mixing tank 100. If the concentration of the first liquid is less than the preset concentration of the first liquid, the third injection pipe 103 is controlled to inject the first liquid with the first flow rate into the mixing tank 100.

The parameter acquisition module 110 and the treatment module 111 may further finely adjust a concentration of the mixed liquid according to a concentration of the second liquid in the mixed liquid specifically as follows. The parameter acquisition module 110 is configured to acquire the concentration of the second liquid in the mixed liquid. The treatment module 111 is configured to control, based on the acquired concentration of the second liquid and a preset concentration of the second liquid, the replenishing pipe to inject the first liquid into the mixing tank 100, or inject the second liquid into the mixing tank 100, so that the concentration of the second liquid in the mixed liquid is close to the preset concentration of the second liquid. The replenishing pipe may include a third injection pipe 103 and a fourth injection pipe 104. Specifically, if the concentration of the second liquid is greater than the preset concentration of the second liquid, the third injection pipe 103 is controlled to inject the first liquid into the mixing tank 100. If the concentration of the second liquid is less than the preset concentration of the second liquid, the fourth injection pipe 104 is controlled to inject the second liquid into the mixing tank 100.

In other embodiments, the concentrations of the first liquid and the second liquid in the mixed liquid may also be finely adjusted; and the accuracy of a direction of fine adjustment is guaranteed through dual verification on the concentration of the first liquid and the preset concentration of the first liquid, the concentration of the second liquid and the preset concentration of the second liquid.

In an example where 1:100 DHF(HF:DIW=1:100 diluted hydrofluoric acid) is formed and a volume of the mixing tank 100 is 40 L, if DIW is injected by the first injection pipe 101 into the mixing tank 100 at a flow rate of 20.25 L/min and HF is injected by the second injection pipe 102 into the mixing tank 100 at a flow rate of 176.5 ml/min, it can be obtained through calculation that the concentration of the second liquid in the mixed solution of the mixing tank 100 is 5500 ppm in this case. In a case where the concentration of 5500 ppm is taken as the preset concentration of the second liquid, if the concentration of the second liquid in the mixed solution of the mixing tank 100 acquired through real-time calculation changes, the third injection pipe 103 is controlled to inject DIW into the mixing tank 100, or the fourth injection pipe 104 is controlled to inject HF into the mixing tank 100.

For example, if the concentration acquired through real-time calculation is 5470 ppm (the concentration fluctuates downward by 30 ppm), the fourth injection pipe 104 is controlled to inject HF into the mixing tank 100 at a speed of 6 ml/min in this case. It is obtained by calculation according to an engineering algorithm that, when 1 ml of HF is added, the concentration of the mixed solution may be increased by about 15 ppm. In this case, the fourth injection pipe 104 is required to inject HF for about 20 s. If the concentration acquired through real-time calculation is 5530 ppm (the concentration fluctuates upward by 30 ppm), the third injection pipe 103 is controlled to inject DIW into the mixing tank 100 at a speed of 0.5 L/min in this case. It is obtained by calculation according to the engineering algorithm that, when 0.22 L of DIW is added, the concentration of the mixed solution may be decreased by about 30 ppm. In this case, the third injection pipe 103 is necessary to inject DIW for about 26.4 s.

It should be noted that the above specific data illustrates the principles of replenishing and injection of this embodiment in terms of specific numbers, so as to facilitate those skilled in the art to understand the solution, which does not constitute any limitation on this embodiment.

Based on the above, the control over injection flow rates is needed in the case of injection through the first injection pipe 101, the third injection pipe 103, the second injection pipe 102 and the fourth injection pipe 104, and then the mixed solution with a required concentration can be obtained. Three methods for controlling a flow rate are provided in this embodiment, which are specifically as follows.

Method 1: the flow rate is controlled through a flow-limiting valve.

Referring to FIG. 1, a first flow-limiting valve 121 is mounted on the third injection pipe 103 and configured to regulate an allowable flow rate of the first liquid; a second flow-limiting valve 122 is mounted on the fourth injection pipe 104 and configured to regulate an allowable flow rate of the second liquid; a third flow-limiting valve 123 is mounted on the first injection pipe 101 and configured to regulate an allowable flow rate of the first liquid; and a fourth flow-limiting valve 124 is mounted on the fourth injection pipe 104 and configured to regulate an allowable flow rate of the second liquid.

Specifically, the first flow-limiting valve 121, the second flow-limiting valve 122, the third flow-limiting valve 123 and the fourth flow-limiting valve 124 each include at least a needle valve or a motor needle feedback valve.

The needle valve is manually adjusted by the relevant staff, so as to adjust an opening degree of the needle valve to achieve the control over the flow rate. The motor needle feedback valve may be adjusted through an operation platform to realize the remote control over the valve by the staff. At the same time, compared with the needle valve (since the opening degree of the needle valve is subject to a change in system pressure, the liquid flow through the needle valve fluctuates, which leads to the instability of the concentration of the first liquid or the second liquid in the mixed liquid), the accuracy of the motor needle feedback valve is higher, and an error range of the allowable flow rate is smaller; moreover, the higher accuracy of the motor needle feedback valve can reduce a flow fluctuation caused by the change in the system pressure, so as to further ensure the stability of the concentration of the first liquid or the second liquid in the mixed solution.

In one example, the first flow-limiting valve 121 is a motor needle feedback valve. The motor needle feedback valve (that is, the first flow-limiting valve 121) includes an acquisition unit 131, a control unit 132 and an operation unit 133. The acquisition unit 131 is configured to acquire a flow rate of a liquid flowing through the motor needle feedback valve. The control unit 132 is connected to the acquisition unit 131, and controls, based on the flow rate of the liquid flowing through the motor needle feedback valve and a preset flow rate, the operation unit 133 to adjust valve opening of the motor needle feedback valve. The operation unit 133 is connected to the control unit 132 and configured to control the valve opening of the motor needle feedback valve. That is, the motor needle feedback valve includes a feedback flowmeter, for adjusting, in real time, the flow rate of the liquid flowing through the motor needle feedback valve to be close to the preset flow rate.

In one example, the allowable flow rate through the third flow-limiting valve 123 ranges from 15 L/min to 25 L/min; the allowable flow rate through the first flow-limiting valve 121 ranges from 0.1 L/min to 0.4 L/min; the allowable flow rate through the fourth flow-limiting valve 124 ranges from 20 ml/min to 250 ml/min; and the allowable flow rate through the third flow-limiting valve 123 ranges from 0 ml/min to 15 ml/min. The flow rates through the flow-limiting valves on the third injection pipe and the fourth injection pipe are set to be lower than those through the flow-limiting valves on the first injection pipe and the third injection pipe, which is conducive to the control over an amount of liquid replenishment and the improvement to the accuracy of fine replenishment, so as to further improve the stability of the concentration of the first liquid or the second liquid in the mixed solution.

Method 2: the flow rate is controlled through a liquid supply device.

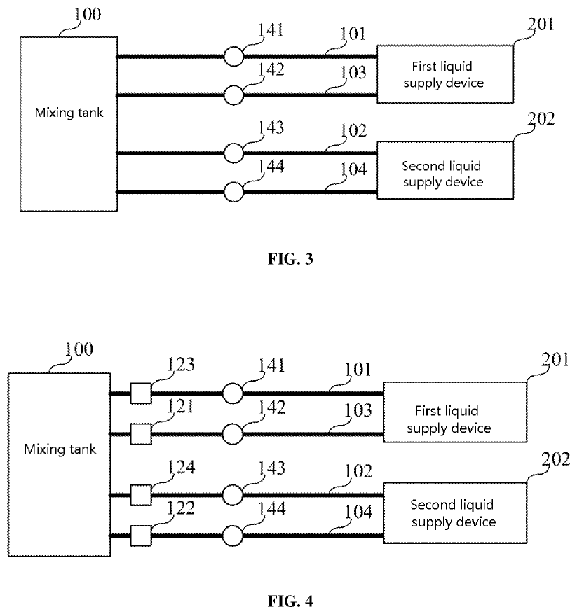

Referring to FIG. 3, a first liquid supply device 201 is connected to the first injection pipe 101 and the third injection pipe 103; and a second liquid supply device 202 is connected to the second injection pipe 102 and the fourth injection pipe 104. The first liquid supply device 201 is configured to supply the first liquid to the first injection pipe 101 and the third injection pipe 103 and adjust a flow rate of the first liquid supplied to the first injection pipe 101 and the third injection pipe 103. The second liquid supply device 202 is configured to supply the second liquid to the second injection pipe 102 and the fourth injection pipe 104 and adjust a flow rate of the second liquid supplied to the second injection pipe 102 and the fourth injection pipe 104.

Method 3: the flow rate is controlled through a liquid supply device and a flow-limiting valve.

Referring to FIG. 4, related discussion is the same as Method 1 and Method 2, and is not described in detail here. Injection flow rates in each injection pipe can be realized more accurately by combining the liquid supply device with the flow-limiting valve.

In addition, since the third injection pipe 103 and the fourth injection pipe 104 are replenishing pipes, they require a lower flow rate of the liquid flowing therethrough, and may be provided with a smaller pipe diameter. That is, a pipe diameter of the third injection pipe 103 is less than that of the first injection pipe 101, and a pipe diameter of the fourth injection pipe 104 is less than that of the second injection pipe 102. In one example, the first injection pipe 101 has an inner diameter ranging from 10 mm to 15 mm and an outer diameter ranging from 15 mm to 20 mm; the third injection pipe 103 has an inner diameter ranging from 3 mm to 5 mm and an outer diameter ranging from 6 mm to 8 mm; the second injection pipe 102 has an inner diameter ranging from 8 mm to 12 mm and an outer diameter ranging from 12 mm to 16 mm; and the fourth injection pipe 104 has an inner diameter ranging from 2 mm to 4 mm and an outer diameter ranging from 3 mm to 5 mm. The replenishing pipe is provided with a slow flow rate and a small pipe diameter, which is conducive to the control over replenishment flow and the improvement to replenishment accuracy, so as to avoid a great fluctuation in the concentration of a main pipe caused by a change in an external environment. In this case, the allowable flow rate through the first injection pipe 101 ranges from 15 L/min to 25 L/min; the allowable flow rate through the third injection pipe 103 ranges from 0.1 L/min to 0.4 L/min; the allowable flow rate through the second injection pipe 102 ranges from 20 ml/min to 250 ml/min; and the allowable flow rate through the fourth injection pipe 104 ranges from 0 ml/min to 15 ml/min.

In this embodiment, the first injection pipe 101, the third injection pipe 103, the second injection pipe 102 and the fourth injection pipe 104 each are provided with a switching valve. The switching valves are configured to turn on the first injection pipe 101, the third injection pipe 103, the second injection pipe 102 and the fourth injection pipe 104 respectively. Specifically, a first switching valve 141 is arranged on the first injection pipe 101; a second switching valve 142 is arranged on the third injection pipe 103; a third switching valve 143 is arranged on the second injection pipe 102; and a fourth switching valve 144 is arranged on the fourth injection pipe 104.

In this embodiment, a liquid storage pipe may also be added in the process of injection of the liquid into the mixing tank 100 to ensure continuous supply of the first liquid and the second liquid. Referring to FIG. 5, the liquid supply system further includes a first liquid storage tank 301. The first liquid storage tank 301 is connected to the second injection pipe 102 and the fourth injection pipe 104. The first liquid storage tank 301 is further connected to at least an air intake pipe and a liquid intake pipe (the liquid intake pipe is a first liquid intake pipe 311, the air intake pipe is a first air intake pipe 331, and a first drainage pipe 321 and a first exhaust pipe 341 are included correspondingly). The first liquid intake pipe 311 is configured to inject the second liquid into the first liquid storage tank 301. The first air intake pipe 331 is configured to inject a drainage gas into the first liquid storage tank 301 and configured to press the second liquid in the first liquid storage tank 301 into the second injection pipe 102 and the fourth injection pipe 104. The liquid supply system further includes a second liquid storage tank 302. The second liquid storage tank 302 is connected to the first injection pipe 101 and the third injection pipe 103. The second liquid storage tank 302 is further connected to at least an air intake pipe and a liquid intake pipe (the liquid intake pipe is a second liquid intake pipe 312, the air intake pipe is a second air intake pipe 332, and a second drainage pipe 322 and a second exhaust pipe 342 are included correspondingly). The second liquid intake pipe 312 is configured to inject the first liquid into the second liquid storage tank 302. The second air intake pipe 332 is configured to inject a drainage gas into the second liquid storage tank 302 and configured to press the first liquid in the second liquid storage tank 302 into the first injection pipe 101 and the third injection pipe 103.

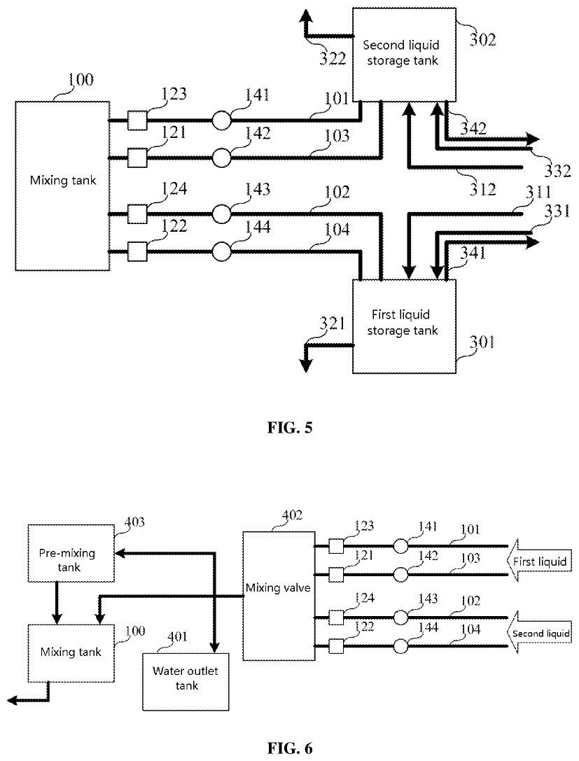

Referring to FIG. 6, in one example, after the liquid is mixed through a mixing valve 402, the mixed liquid is introduced through a liquid outlet pipe. Specifically, the liquid outlet pipe is connected to a water outlet tank 401, the mixing tank 100 and a pre-mixing tank 403. When conveying the mixed liquid to the mixing tank 100, the mixing valve 402 may first convey the mixed liquid into the water outlet tank 401, and then convey the mixed liquid into the mixing tank 100 after the concentration of the first liquid or the second liquid in the mixed liquid is stable. The mixed liquid in the mixing tank 100 in which the concentration of the first liquid or the second liquid is stable is directly applied to a semiconductor process. The pre-mixing tank 403 is equivalent to an expansion container of the mixing tank 100. The mixing valve 402 conveys the mixed liquid into the pre-mixing tank 403 while conveying the mixed liquid into the mixing tank 100. The mixed liquid in the pre-mixing tank 403 may flow back into the mixing tank 100.

It should be noted that, in other embodiments, the third injection pipe may serve as a branch pipe of the first injection pipe, and the fourth injection pipe may serve as a branch pipe of the second injection pipe. The first injection pipe may be connected to the second injection pipe by a cleaning pipe and configured to inject a cleaning liquid from one injection pipe to clean the entire liquid supply system.

Compared with the related art, the first injection pipe injects the first liquid into the mixing tank, the second injection pipe injects the second liquid into the mixing tank, the first liquid and the second liquid are mixed in the mixing tank to obtain a mixed solution, the concentration of the first liquid in the mixed solution is acquired through the parameter acquisition module and is compared with the preset concentration of the first liquid, and the first liquid or the second liquid is replenished through the replenishing pipe according to a comparison result; that is, the concentration of the first liquid in the mixed liquid of the mixing tank is finely adjusted, so that the concentration of the mixed liquid formed by mixing is more stable.

It should be noted that all the units involved in this embodiment are logical units. In a practical application, a logical unit may be a physical unit or a part of the physical unit, or may be implemented through a combination of a plurality of physical units. In addition, in order to highlight the innovative portion of the present application, units that are not closely related to the technical problem set forth in the present application are not introduced in this embodiment, which, however, does not indicate that other units do not exist in this embodiment.

Another embodiment of the present application relates to a liquid supply system. This embodiment is substantially the same as the above embodiment, with a difference that this embodiment is illustrated with an example in which the parameter acquisition module is a flowmeter. Parts the same as those in the above embodiment are not described in detail in this embodiment. The liquid supply system according to this embodiment is specifically described below with reference to the drawings.

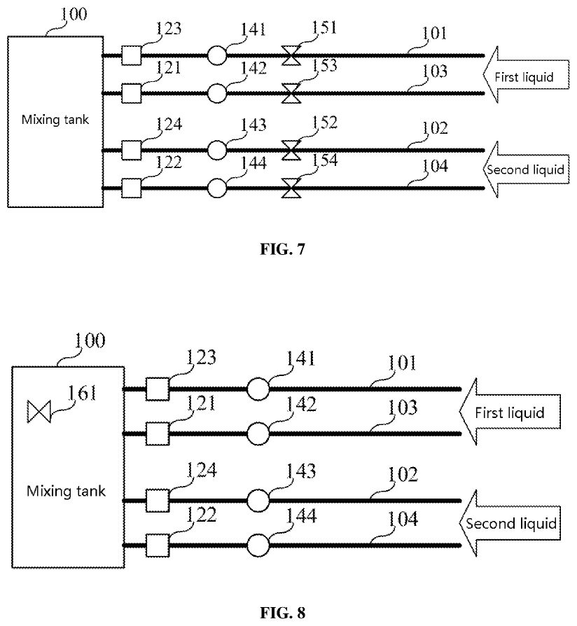

Referring to FIG. 7, the liquid supply system further includes a first flowmeter 151, a second flowmeter 152, a third flowmeter 153 and a fourth flowmeter 154. The first flowmeter 151 is arranged on the first injection pipe 101 and configured to acquire a third flow rate of the first liquid injected by the first injection pipe 101 into the mixing tank 100. The second flowmeter 152 is arranged on the second injection pipe 102 and configured to acquire a fourth flow rate of the second liquid injected by the second injection pipe 102 into the mixing tank 100.

In this case, the parameter acquisition module 110 further includes a parameter calculation unit (not shown) configured to calculate a concentration of the first liquid or the second liquid in the mixed liquid based on the third flow rate and the fourth flow rate. In one embodiment, the flowmeter may conduct statistics on total amounts of the first liquid and the second liquid injected by the first injection pipe 101 and the second injection pipe 102 into the mixing tank 100 in a preset time, and then calculate the concentration of the first liquid in the mixed liquid of the mixing tank 100. The preset time may be 30 s, 25 s, 20 s, 15 s, 10 s or 5 s.

The treatment module 111 is configured to control, based on the acquired concentration of the first liquid and a preset concentration of the first liquid, the replenishing pipe to inject the first liquid with a first flow rate into the mixing tank 100, or inject the second liquid with a second flow rate into the mixing tank 100, so that the concentration of the first liquid in the mixed liquid is close to the preset concentration of the first liquid. Specifically, the replenishing pipe includes a third injection pipe 103 and a fourth injection pipe 104. Therefore, the third injection pipe 103 may be controlled to inject the first liquid with the first flow rate into the mixing tank 100, or the fourth injection pipe 104 may be controlled to inject the second liquid with the second flow rate into the mixing tank 100. In one example, the concentration of the first liquid in the mixed liquid is allowed to be within ±5% of the preset concentration of the first liquid, for example, within ±4%, ±3%, ±2% or ±1%, or further within ±0.5%.

Alternatively, the treatment module 111 is configured to control, based on the acquired concentration of the second liquid and a preset concentration of the second liquid, the replenishing pipe to inject the first liquid into the mixing tank 100, or inject the second liquid into the mixing tank 100, so that the concentration of the second liquid in the mixed liquid is close to the preset concentration of the second liquid. Specifically, the third injection pipe 103 may be controlled to inject the first liquid into the mixing tank 100, or the fourth injection pipe 104 may be controlled to inject the second liquid into the mixing tank 100. In one example, the concentration of the second liquid in the mixed liquid is allowed to be within ±5% of the preset concentration of the second liquid, for example, within ±4%, ±3%, ±2% or ±1%, or further within ±0.5%.

In this case, the flow rate of the first liquid or the second liquid finely replenished may be observed in real time through the third flowmeter 153 and the fourth flowmeter 154. The third flowmeter 153 is arranged on the third injection pipe 103 and configured to acquire a flow rate of the first liquid injected by the third injection pipe 103 into the mixing tank 100. The fourth flowmeter 154 is arranged on the fourth injection pipe 104 and configured to acquire a flow rate of the second liquid injected by the fourth injection pipe 104 into the mixing tank 100.

Since the above embodiment and this embodiment are corresponding to each other, this embodiment and the above embodiment can collaborate with each other for implementation. Related technical details described in the above embodiment are still valid in this embodiment, and technical effects that can be achieved in the above embodiment may also be achieved in this embodiment, and are not described herein to avoid repetition. Correspondingly, related technical details described in this embodiment may also be applied to the above embodiment.

Yet another embodiment of the present application relates to a liquid supply system. This embodiment is substantially the same as the above embodiment, with a difference that this embodiment is illustrated with an example in which the parameter acquisition module is a concentration meter. Parts the same as those in the above embodiment are not described in detail in this embodiment. The liquid supply system according to this embodiment is specifically described below with reference to the drawings.

Referring to FIG. 8, the liquid supply system further includes a first concentration meter 161 arranged in the mixing tank 100 and configured to acquire the concentration of the first liquid in the mixed liquid or a concentration of the second liquid in the mixed liquid.

A concentration of the mixed solution in the mixing tank 100 is acquired directly through the concentration meter, so as to avoid data calculation and acquire a concentration value faster and more conveniently. At the same time, compared with the first method for arranging the concentration meter, in the second method for arranging the concentration meter, the first liquid and the second liquid are mixed for a longer time and mixed more sufficiently, and data obtained is more accurate.

Since the above embodiment and this embodiment are corresponding to each other, this embodiment and the above embodiment can collaborate with each other for implementation. Related technical details described in the above embodiment are still valid in this embodiment, and technical effects that can be achieved in the above embodiment may also be achieved in this embodiment, and are not described herein to avoid repetition. Correspondingly, related technical details described in this embodiment may also be applied to the above embodiment.

Still another embodiment of the present application relates to a liquid supply system. This embodiment is substantially the same as the above embodiment, with a difference that the mixed solution obtained in this embodiment contains more than two components. Parts the same as those in the above embodiment are not described in detail in this embodiment. The liquid supply system according to this embodiment is specifically described below with reference to the drawings.

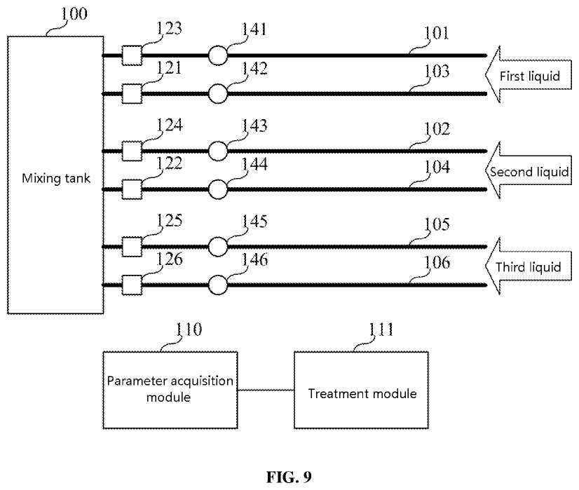

Referring to FIG. 9, the liquid supply system further includes a fifth injection pipe 105 and a sixth injection pipe 106. Similar to the above embodiment, the fifth injection pipe 105 further includes a fifth switching valve 145 and a fifth flow-limiting valve 125; and the sixth injection pipe further includes a sixth switching valve 146 and a sixth flow-limiting valve 126.

The fifth injection pipe 105 is configured to inject a third liquid into the mixing tank 100 to form the mixed liquid.

The parameter acquisition module (not shown) is further configured to acquire a concentration of the third liquid in the mixed liquid.

The treatment module (not shown) is further configured to control, based on the acquired concentration of the third liquid and a preset concentration of the third liquid, the sixth injection pipe 106 to inject the third liquid with a fifth flow rate into the mixing tank 100, so that the concentration of the third liquid in the mixed liquid is close to the preset concentration of the third liquid.

In one example, the concentration of the third liquid in the mixed liquid is allowed to be within ±5% of the preset concentration of the third liquid, for example, within ±4%, ±3%, ±2% or ±1%, or further within ±0.5%.

It is appreciated by those skilled in the art that liquids containing three components are mixed through the fifth injection pipe 105 and the sixth injection pipe 106, and the stability of respective concentrations of the three components in the mixed liquid is ensured at the same time. The same applies to mixing of liquids containing four components, five components, or even more components. The stability of respective concentrations of the components in the mixed liquid is ensured at the same time.

Compared with the related art, the first injection pipe injects the first liquid into the mixing tank, the second injection pipe injects the second liquid into the mixing tank, the first liquid and the second liquid are mixed in the mixing tank to obtain a mixed solution, the concentration of the first liquid in the mixed solution is acquired through the parameter acquisition module and is compared with the preset concentration of the first liquid, and the first liquid is replenished through the third injection pipe or the second liquid is replenished through the fourth injection pipe according to a comparison result; that is, the concentration of the first liquid in the mixed liquid of the mixing tank is finely adjusted in real time, so that the concentration of the mixed liquid formed by mixing is more stable.

Since the above embodiment and this embodiment are corresponding to each other, this embodiment and the above embodiment can collaborate with each other for implementation. Related technical details described in the above embodiment are still valid in this embodiment, and technical effects that can be achieved in the above embodiment may also be achieved in this embodiment, and are not described herein to avoid repetition. Correspondingly, related technical details described in this embodiment may also be applied to the above embodiment.

A fifth embodiment of the present application relates to a liquid supply method. The liquid supply method according to this embodiment is described in detail below. Parts the same as or corresponding to those in the above embodiment are not described in detail below.

The liquid supply method includes: acquiring a concentration of a first liquid in a mixed liquid and a preset concentration of the first liquid; and controlling, based on the acquired concentration of the first liquid and the preset concentration of the first liquid, a replenishing pipe to inject the first liquid with a first flow rate or a second liquid into a mixing tank, so that the concentration of the first liquid in the mixed liquid is close to the preset concentration of the first liquid.

In this embodiment, the replenishing pipe may include a third injection pipe and a fourth injection pipe. The third injection pipe is configured to replenish the first liquid into the mixing tank 100. The fourth injection pipe is configured to finely replenish the second liquid into the mixing tank. In other embodiments, the replenishing pipe may also be provided with one or more injection pipes. In addition, when the replenishing pipe is provided with one injection pipe, when the first liquid in the replenishing pipe is changed to the second liquid (or when the second liquid in the replenishing pipe is changed to the first liquid), the replenishing pipe is cleaned using a cleaning liquid first to prevent a difference in concentration caused by a residual liquid in the replenishing pipe.

In one example, the concentration of the first liquid in the mixed liquid is allowed to be within ±5% of the preset concentration of the first liquid, for example, within ±4%, ±3%, ±2% or ±1%, or further within ±0.5%.

Specifically, the step of controlling, based on the acquired concentration of the first liquid and a preset concentration of the first liquid, the third injection pipe to inject the first liquid with the first flow rate into the mixing tank, or controlling the fourth injection pipe to inject the second liquid with a second flow rate into the mixing tank includes: controlling the fourth injection pipe to inject the second liquid into the mixing tank if the concentration of the first liquid in the mixed liquid is greater than the preset concentration of the first liquid; and controlling the third injection pipe to inject the first liquid into the mixing tank if the concentration of the first liquid in the mixed liquid is less than the preset concentration of the first liquid.

Alternatively, the concentration of the second liquid in the mixed liquid and a preset concentration of the second liquid are acquired; and based on the acquired concentration of the second liquid and the preset concentration of the second liquid, the third injection pipe is controlled to inject the first liquid into the mixing tank, or the fourth injection pipe is controlled to inject the second liquid into the mixing tank, so that the concentration of the second liquid in the mixed liquid is close to the preset concentration of the second liquid.

In one example, the concentration of the second liquid in the mixed liquid is allowed to be within ±5% of the preset concentration of the second liquid, for example, within ±4%, ±3%, ±2% or ±1%, or further within ±0.5%.

Specifically, the step of controlling, based on the acquired concentration of the second liquid and a preset concentration of the second liquid, the third injection pipe to inject the first liquid into the mixing tank, or controlling the fourth injection pipe to inject the second liquid into the mixing tank includes: controlling the third injection pipe to inject the second liquid into the mixing tank if the concentration of the second liquid in the mixed liquid is greater than the preset concentration of the second liquid; and controlling the fourth injection pipe to inject the first liquid into the mixing tank if the concentration of the second liquid in the mixed liquid is less than the preset concentration of the second liquid.

It should be noted that, in this embodiment, the first liquid is deionized water (DIW), the second liquid is hydrofluoric acid (49% HF), and the mixed solution formed in the mixing tank 100 is diluted hydrofluoric acid (DHF). In other embodiments, the first liquid and the second liquid may be any liquid; that is, the mixed solution in the mixing tank is any mixed solution of the first liquid and the second liquid.

In one example where 1:100 DHF (HF:DIW=1:100 diluted hydrofluoric acid) is formed, if DIW is injected by the first injection pipe 101 into the mixing tank 100 at a flow rate of 20.25 L/min and HF is injected by the second injection pipe 102 into the mixing tank 100 at a flow rate of 176.5 ml/min, it can be obtained through calculation that the concentration of the second liquid in the mixed solution of the mixing tank 100 is 5500 ppm in this case. In a case where the concentration of 5500 ppm is taken as the preset concentration of the second liquid, if the concentration of the second liquid in the mixed solution of the mixing tank 100 acquired through real-time calculation changes, the third injection pipe 103 is controlled to inject DIW into the mixing tank 100 or the fourth injection pipe 104 is controlled to inject HF into the mixing tank 100.

For example, if the concentration acquired through real-time calculation is 5470 ppm (the concentration fluctuates downward by 30 ppm), the fourth injection pipe 104 is controlled to inject HF into the mixing tank 100 at a speed of 6 ml/min in this case. It is obtained by calculation according to an engineering algorithm that, when 1 ml of HF is added, the concentration of the mixed solution may be increased by about 15 ppm. In this case, the fourth injection pipe 104 is required to inject HF for about 20 s. If the concentration acquired through real-time calculation is 5530 ppm (the concentration fluctuates upward by 30 ppm), the third injection pipe 103 is controlled to inject DIW into the mixing tank 100 at a speed of 0.5 L/min in this case. It is obtained by calculation according to the engineering algorithm that, when 0.22 L of DIW is added, the concentration of the mixed solution may be decreased by about 30 ppm. In this case, the third injection pipe 103 is required to inject DIW for about 26.4 s.

It should be noted that the above specific data illustrates the principles of replenishing and injection of this embodiment in terms of specific numbers, so as to facilitate those skilled in the art to understand the solution, which does not constitute any limitation on this embodiment.

Compared with the related art, the first liquid is replenished through the third injection pipe or the second liquid is replenished through the fourth injection pipe according to a comparison result; that is, the concentration of the first liquid in the mixed liquid of the mixing tank is finely adjusted, so that the concentration of the mixed liquid formed by mixing is more stable.

Division of the steps of the above methods is only for clear description, and during implementation, the steps may be combined into one step or some steps may be split into multiple steps, all of which shall fall within the protection scope of the patent provided that a same logical relationship is included. Insignificant modifications added to or insignificant designs introduced in an algorithm or a procedure without changing the core of the algorithm or the procedure shall fall within the protection scope of the patent.

Since the above embodiment and this embodiment are corresponding to each other, this embodiment and the above embodiment can collaborate with each other for implementation. Related technical details described in the above embodiment are still valid in this embodiment, and technical effects that can be achieved in the above embodiment may also be achieved in this embodiment, and are not described herein to avoid repetition. Correspondingly, related technical details described in this embodiment may also be applied to the above embodiment.

Those of ordinary skill in the art may understand that the above embodiments are specific embodiments for implementing the present application. However, in practical applications, various changes in forms and details may be made thereto without departing from the spirit and scope of the present application.

1. A liquid supply system, comprising:
a mixing tank, the mixing tank being connected to at least a first injection pipe, a second injection pipe and a replenishing pipe;
the first injection pipe and the second injection pipe being configured to inject a first liquid and a second liquid into the mixing tank respectively, so as to form a mixed liquid;
a parameter acquisition module configured to acquire a concentration of the first liquid in the mixed liquid; and
a treatment module configured to control, based on the acquired concentration of the first liquid and a preset concentration of the first liquid, the replenishing pipe to inject the first liquid with a first flow rate into the mixing tank, or inject the second liquid with a second flow rate into the mixing tank, so that the concentration of the first liquid in the mixed liquid is close to the preset concentration of the first liquid.

2. The liquid supply system according to claim 1, wherein the replenishing pipe comprises a third injection pipe and a fourth injection pipe;
wherein the step of controlling the replenishing pipe to inject the first liquid with a first flow rate into the mixing tank, or inject the second liquid with a second flow rate into the mixing tank comprises: controlling the third injection pipe to inject the first liquid with the first flow rate into the mixing tank, or controlling the fourth injection pipe to inject the second liquid with the second flow rate into the mixing tank.

3. The liquid supply system according to claim 1, wherein the parameter acquisition module comprises at least one of a flowmeter and a concentration meter.

4. The liquid supply system according to claim 3, wherein the flowmeter comprises:
a first flowmeter, the first flowmeter being arranged on the first injection pipe and configured to acquire a third flow rate of the first liquid injected by the first injection pipe into the mixing tank; and
a second flowmeter, the second flowmeter being arranged on the second injection pipe and configured to acquire a fourth flow rate of the second liquid injected by the second injection pipe into the mixing tank; and
the parameter acquisition module further comprises: a parameter calculation unit configured to calculate the concentration of the first liquid in the mixed liquid or a concentration of the second liquid in the mixed liquid based on the third flow rate and the fourth flow rate.

5. The liquid supply system according to claim 3, wherein the concentration meter is arranged in the mixing tank and configured to acquire the concentration of the first liquid in the mixed liquid or the concentration of the second liquid in the mixed liquid.

6. The liquid supply system according to claim 2, comprising:
a first flow-limiting valve mounted on the third injection pipe and configured to regulate an allowable flow rate of the first liquid;
a second flow-limiting valve mounted on the fourth injection pipe and configured to regulate an allowable flow rate of the second liquid;
a third flow-limiting valve mounted on the first injection pipe and configured to regulate an allowable flow rate of the first liquid; and
a fourth flow-limiting valve mounted on the second injection pipe and configured to regulate an allowable flow rate of the second liquid.

7. The liquid supply system according to claim 6, wherein the allowable flow rate through the first flow-limiting valve ranges from 0.1 L/min to 0.4 L/min; and the allowable flow rate through the second flow-limiting valve ranges from 0 ml/min to 15 ml/min.

8. The liquid supply system according to claim 6, wherein the allowable flow rate through the third flow-limiting valve ranges from 15 L/min to 25 L/min; and the allowable flow rate through the fourth flow-limiting valve ranges from 20 ml/min to 250 ml/min.

9. The liquid supply system according to claim 6, wherein the first flow-limiting valve, the second flow-limiting valve, the third flow-limiting valve and the fourth flow-limiting valve each comprise a needle valve.

10. The liquid supply system according to claim 6, wherein the first flow-limiting valve, the second flow-limiting valve, the third flow-limiting valve and the fourth flow-limiting valve each comprise a motor needle feedback valve.

11. The liquid supply system according to claim 1, further comprising:
a fifth injection pipe and a sixth injection pipe that are connected to the mixing tank;
the fifth injection pipe being configured to inject a third liquid into the mixing tank to form the mixed liquid;
the parameter acquisition module being further configured to acquire a concentration of the third liquid in the mixed liquid; and
the treatment module being further configured to control, based on the acquired concentration of the third liquid and a preset concentration of the third liquid, the sixth injection pipe to inject the third liquid with a fifth flow rate into the mixing tank, so that the concentration of the third liquid in the mixed liquid is close to the preset concentration of the third liquid.

12. The liquid supply system according to claim 2, wherein a pipe diameter of the third injection pipe is less than that of the first injection pipe, and a pipe diameter of the fourth injection pipe is less than that of the second injection pipe.

13. The liquid supply system according to claim 1, further comprising: a mixing valve with one end connected to the mixing tank and the other end connected to the first injection pipe, the second injection pipe and the replenishing pipe and configured to uniformly mix the first liquid and the second liquid injected by the first injection pipe, the second injection pipe and the replenishing pipe and then inject the first liquid and the second liquid into the mixing tank.

14. A liquid supply method for the liquid supply system according to claim 1, comprising:
acquiring a concentration of a first liquid in a mixed liquid and a preset concentration of the first liquid; and
controlling, based on the acquired concentration of the first liquid and the preset concentration of the first liquid, the replenishing pipe to inject the first liquid with a first flow rate or a second liquid into the mixing tank, so that the concentration of the first liquid in the mixed liquid is close to the preset concentration of the first liquid.
